(19) United States
(12) Patent Application Publication
(10) Pub. No.: US 2025/0264676 A1
(43) Pub. Date: Aug. 21, 2025

(54) MANUFACTURING METHOD OF PACKAGE SUBSTRATE AND OPTICAL DEVICE

(71) Applicant: Dyi-Chung HU, Hsinchu County (TW)

(72) Inventor: Dyi-Chung HU, Hsinchu County (TW)

(21) Appl. No.: 19/055,507

(22) Filed: Feb. 18, 2025

Related U.S. Application Data
(60) Provisional application No. 63/555,082, filed on Feb. 18, 2024.

(51) Int. Cl. G02B 6/42; H01L 21/48; H01L 25/16

(52) U.S. Cl. CPC G02B 6/4246; H01L 21/486; H01L 25/167

(57) ABSTRACT

A manufacturing method of a package substrate includes providing a support structure; forming a first photo-sensitive layer over the support structure; patterning the first photo-sensitive layer to form first openings; curing the first photo-sensitive layer; and forming a functional structure in the first openings. An optical device is also provided.

### CROSS-REFERENCE TO RELATED APPLICATION

This application claims the priority benefit of the U.S. provisional application Ser. No. 63/555,082, filed on Feb. 18, 2024. The entirety of the above-mentioned patent application is hereby incorporated by reference herein and made a part of this specification.

### BACKGROUND

### Technical Field

The disclosure relates to a manufacturing method of package substrate and an optical device.

### Description of Related Art

With the vigorous development of the electronic industry, to achieve high density and high efficiency, various electronic products are becoming lighter, thinner, shorter, and smaller. For example, a thin and high-density package structure is usually expected to make an electronic product thinner. Therefore, with a decreasing semiconductor chip size and package structure size, how to develop a matching substrate without greatly increasing manufacturing costs has become an issue to be urgently resolved.

### SUMMARY

A manufacturing method of a package substrate includes providing a support structure; forming a first photo-sensitive layer over the support structure; patterning the first photo-sensitive layer to form first openings; curing the first photo-sensitive layer; and forming a functional structure in the first openings.

An optical device includes a package substrate including a first optical fiber array unit; a first transceiver disposed on and electrically connected to the package substrate; and a second transceiver disposed on and electrically connected to the package substrate. A first electrical signal and a first optical signal are transferred between the first transceiver and the second transceiver by the first optical fiber array unit. The first electrical signal and the first optical signal are converted by the first transceiver and the second transceiver.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 5 are partial schematic cross-sectional views illustrating a manufacturing method of a package substrate according to some embodiments of the disclosure.

FIG. 6 is a partial schematic cross-sectional view illustrating a package substrate according to some embodiments of the disclosure.

FIG. 7 to FIG. 9 are partial schematic cross-sectional views illustrating a manufacturing

method of a package substrate according to some embodiments of the disclosure.

FIG. 10 is a partial schematic cross-sectional view illustrating a package substrate according to some embodiments of the disclosure.

FIG. 11 is a flow diagram of some embodiments of a manufacturing method of a package substrate.

FIG. 12 is a partial schematic cross-sectional view illustrating an optical device according to some embodiments of the disclosure.

FIG. 13 is a partial schematic top view corresponding to FIG. 12.

FIG. 14 and FIG. 15 are partial schematic cross-sectional views illustrating a package substrate according to some embodiments of the disclosure.

FIG. 16 is a partial schematic top view illustrating optical devices according to some embodiments of the disclosure.

FIG. 17 is a partial schematic cross-sectional view illustrating optical devices according to FIG. 16.

### DESCRIPTION OF THE EMBODIMENTS

Exemplary embodiments of the disclosure are described below comprehensively with reference to the figures, but the disclosure may also be implemented in different ways and should not be construed as limited to the embodiments described herein. In the drawings, for the sake of clarity, the size and thickness of various regions, parts, and layers may not be drawn to actual scale. In order to facilitate understanding, the same elements in the following description are described with the same symbols.

The disclosure is more comprehensively described with reference to the figures of this embodiment. However, the disclosure may also be implemented in various different forms, and is not limited to the embodiments in the present specification. Thicknesses, dimensions, and sizes of layers or regions in the drawings are exaggerated for clarity. The same reference numbers are used in the drawings and the description to indicate the same or like parts, which are not repeated in the following embodiments.

Directional terms (for example, upper, lower, right, left, front, back, top, and bottom) used herein only refer to the graphical use, and are not intended to imply absolute orientation.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion.

Unless otherwise defined, all terms (including technical and scientific terms) used herein have the same meaning as that commonly understood by one of ordinary skill in the art to which this disclosure belongs.

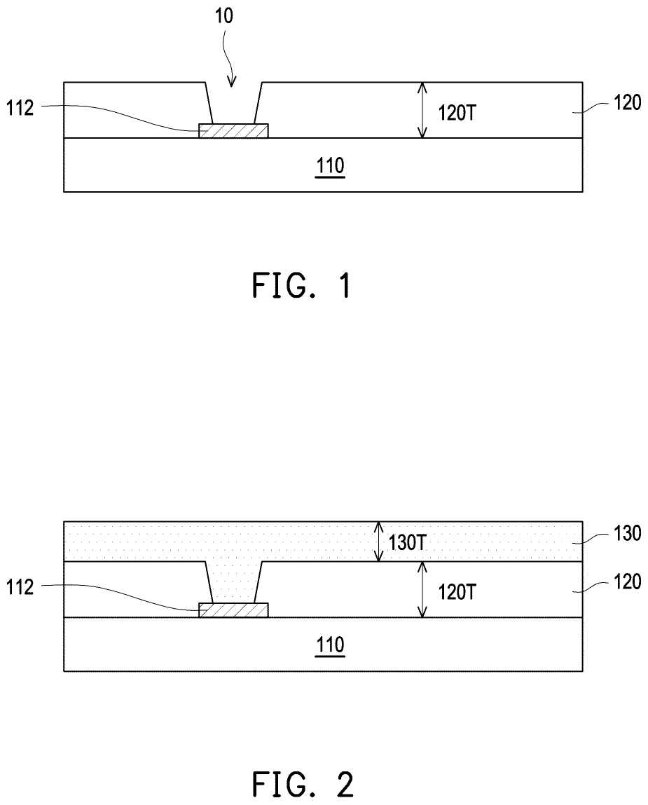

FIG. 1 to FIG. 5 are partial schematic cross-sectional views illustrating a manufacturing method of a package substrate according to some embodiments of the disclosure. FIG. 6 is a partial schematic cross-sectional view illustrating a package substrate according to some embodiments of the disclosure. In package substrate, requirements of a fine circuitry (may range from 0.4 um to 2 um) are increasingly important and many problems are also derived. For example, conventional semi-additive processes are usually used to produce the fine circuitry, however, the etching of the seed layer is resulted to shrink and change in the conductive trace (such as copper trace) with removal seed layer, such that undesirable dimensional conductive trace may decrease the reliability of the package substrate. In the present disclosure at least illustrated in FIG. 1 to FIG. 5, a photo-sensitive layer is used to create well-defined openings for embedded a circuit structure, by doing so, the circuit structure embedded in the photo-sensitive layer may be better retained in dimensions, thereby the reliability of the package substrate may be increased. In addition, the photo-sensitive layer may also reduce the manufacturing costs of the package substrate. Moreover, present patent applications integrate the electric and optical connections in one integrated optical electrical substrate.

Referring to FIG. 1, a support structure 110 is provided. In some embodiments, the support structure 110 may be a circuit board having a conductive trace, for example, the support structure 110 may be a PCB substrate or the like, but the disclosure is not limited thereto. In other embodiments, the support structure 110 may be a dummy board free from the conductive trace, for example, the support structure 110 may be made of glass or other suitable materials, as long as the materials may withstand the subsequent process and simultaneously support the overlying structure.

And then, at least one terminal 112 is formed on the support structure 110. In some embodiments, the terminal 112 may be formed of copper, gold, nickel, aluminum, platinum, tin, combinations thereof, alloys thereof, or other suitable conductive materials by suitable depositing process on the support structure 110, but the disclosure is not limited thereto. Here, the terminal 112 may be electrically connected or electrically isolated to the support structure 110 based on the requirements.

In the embodiment, a dielectric layer 120 is formed over the support structure 110. For example, the dielectric layer 120 may be formed as follow. First, a photo-sensitive material (such as a photo-sensitive polyimide or the like) is deposited over the support structure 110. In one embodiment, the photo-sensitive material may be formed in liquid form, but the disclosure is not limited thereto, in another embodiment, the photo-sensitive material may be formed in film form. And then, the photo-sensitive material is patterned to form at least one opening 10 (may be referred as via) to expose the terminal 112. In some embodiments, a photolithography process including an exposure process and a development process and an etching process are used to pattern the photo-sensitive material. For example, the photolithography process may use a laser direct imaging tool or the like to well control a size of the opening 10. Next, the photo-sensitive material is cured to form the dielectric layer 120. In some embodiments, a thickness 120T of the dielectric layer 120 may be 10 micrometers (um) or other suitable values.

Referring to FIG. 2, a photo-sensitive layer 130 is formed over the support structure 110. For example, the photo-sensitive layer 130 (such as a photo-sensitive polyimide or the like) is deposited on the dielectric layer 120 and in the opening 10. In this step, the photo-sensitive layer 130 may be formed in liquid form, but the disclosure is not limited thereto, the photo-sensitive layer 130 also may be formed in film form. In some embodiments, a thickness 130T of the photo-sensitive layer 130 over the dielectric layer 120 is thinner than the thickness 120T of the dielectric layer 120, for example, a thickness 130T of the photo-sensitive layer 130 may be 5 micrometers (um) or other suitable values.

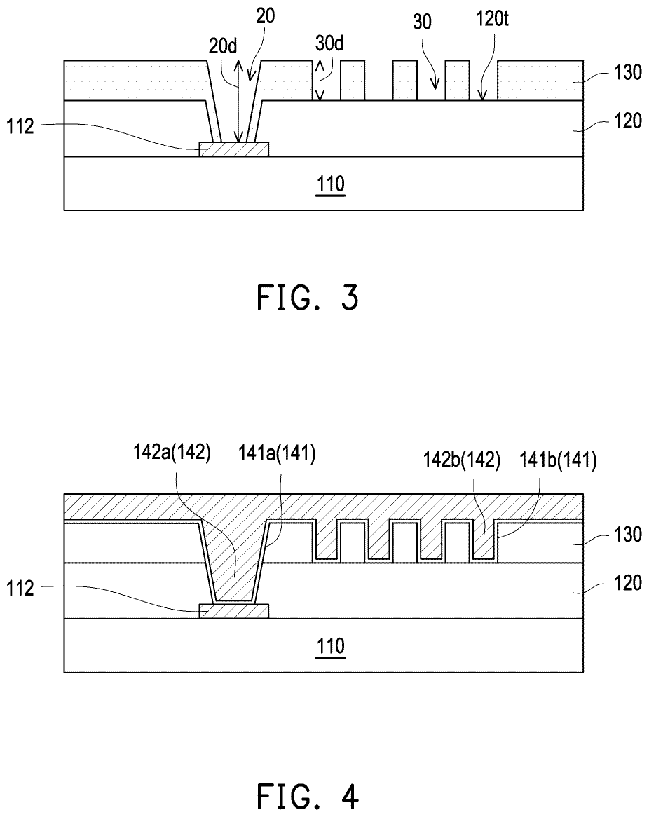

Referring to FIG. 3, the photo-sensitive layer 130 is patterned to form an opening 20 (may be referred another via) exposing the terminal 112 and a plurality of openings 30 (may be referred as trenches) exposing a top surface 120t of the dielectric layer 120, in this way, different depths of the openings are formed in the photo-sensitive layer 130. For example, a depth 20d of the opening 20 is deeper than a depth 30d of the opening 30. Further, a size of the opening 20 may be bigger than or smaller than a size of the opening 10. Here, the size may be diameter or the like. Moreover, materials of the dielectric layer 120 may be same as materials of the photo-sensitive layer 130, but the disclosure is not limited thereto, materials of the dielectric layer 120 may also be different from materials of the photo-sensitive layer 130 based on the design requirement.

In the embodiments, a photolithography process including an exposure process and a development process and an etching process are used to pattern the photo-sensitive layer 130. For example, stepper exposure may be used to achieve different depths of the openings (the opening 20 and the opening 30) by using different photomasks (not shown), but the disclosure is not limited thereto. In some embodiments, the laser direct imaging (LDI) is used to expose the deeper opening 20 with higher energy and expose the shallow openings 30 with lower energy, thereby the photomasks may be omitted.

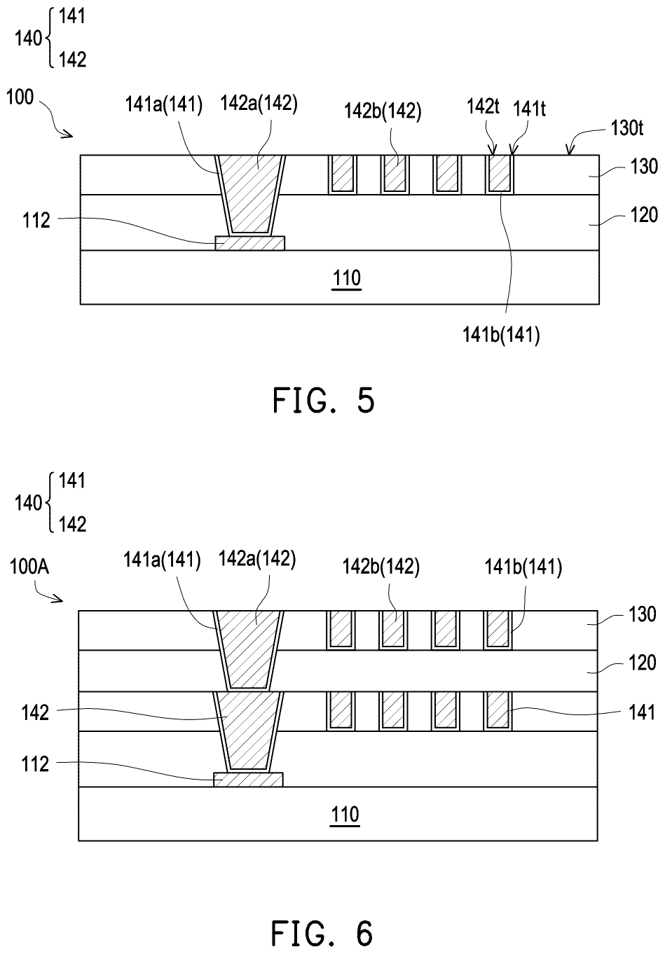

Referring to FIG. 4 and FIG. 5, the photo-sensitive layer 130 is cured. Next, a circuit structure 140 is formed in the opening 20 and the openings 30, wherein the circuit structure 140 may be a functional structure. In the embodiment, the circuit structure 140 is manufactured as follow. In FIG. 4, a seed layer 141 is formed over the support structure 110, wherein the seed layer 141 includes a seed via portion 141a formed in the opening 20 and seed trench portions 141b formed in the openings 30. In some embodiments, the seed layer 141 is conformally formed by sputtering with Ti/Cu. And then, a conductive layer 142 is formed on the seed layer 141, wherein the conductive layer 142 includes a conductive via portion 142a formed on the seed via portion 141a of the seed layer 141 and conductive trench portions 142b formed on the seed trench portions 141b of the seed layer 141. Next, in FIG. 5, a planarization process is performed, such that a top surface 130t of the photo-sensitive layer 130 is coplanar with a top surface of the circuit structure 140 (such as a top surface 141t of the seed layer 141 and a top surface 142t of the conductive layer 142). Here, the planarization process may include CMP, grinding, chemical etching, or a combination thereof. The manufacturing of a package substrate 100 is roughly completed via the above steps.

On the other hand, when the support structure 110 is the circuit board, the support structure 110 is not removed after forming the circuit structure 140, in contrast, when the support structure 110 is the dummy board, the support structure 110 is removed after forming the circuit structure 140.

It should be noted that the package substrate 100 having two layers is an example for illustrating, numbers of the package substrate 100 may be not limited, that is to say, in another embodiment, as shown in FIG. 6, for higher integrating, another dielectric layer 120, another photo-sensitive layer 130, and another circuit structure 140 may be formed by similar method in FIG. 1 to FIG. 5 on the support structure 110 to constitute a package substrate 100A. In yet another embodiment (not shown), the dielectric layer 120 may be omitted, that is to say, only the photo-sensitive layer 130 and the circuit structure 140 are direct in contact with the support structure 110 and the terminal 112 respectively.

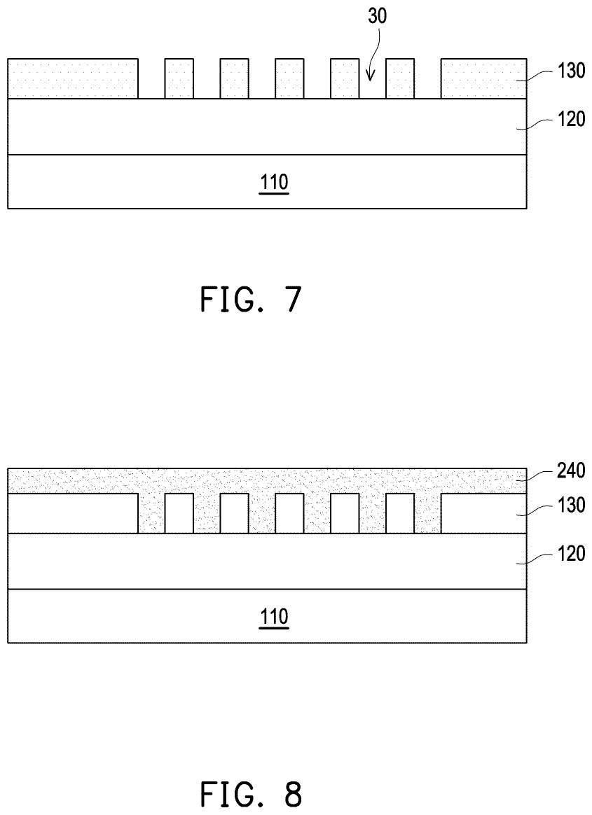

FIG. 7 to FIG. 9 are partial schematic cross-sectional views illustrating a manufacturing method of a package substrate according to some embodiments of the disclosure. FIG. 10 is a partial schematic cross-sectional view illustrating a package substrate according to some embodiments of the disclosure. In package substrate, an optical application is another issue and many problems are also derived. For example, as the demanding calculation power of artificial intelligence increases, the bandwidth of communication between chips also increases. However, the communication bandwidth is limited. In the present disclosure at least illustrated in FIG. 7 to FIG. 9, a photo-sensitive layer is used to create well-defined openings for embedded optical structure in the package substrate. To be specific, it may create higher quality multiple channels to increase the density of optical fiber array unit in the package substrate, thereby the communication bandwidth may be improved. In addition, the photo-sensitive layer may also reduce the manufacturing costs of the package substrate.

Referring to FIG. 7 to FIG. 8, similar to FIG. 1 to FIG. 3, the same reference numbers are used in the drawings and the description to indicate the same or like parts, which are not repeated in the following embodiments. The support structure 110 is provided. And then, the dielectric layer 120 is formed over the support structure 110. Next, the photo-sensitive layer 130 is formed over the support structure 110 and the photo-sensitive layer 130 is patterned to form the openings 30. To be specific, based on different functionalities in the package substrate, the opening 10 in FIG. 1 and the opening 20 in FIG. 2 are omitted in this embodiment.

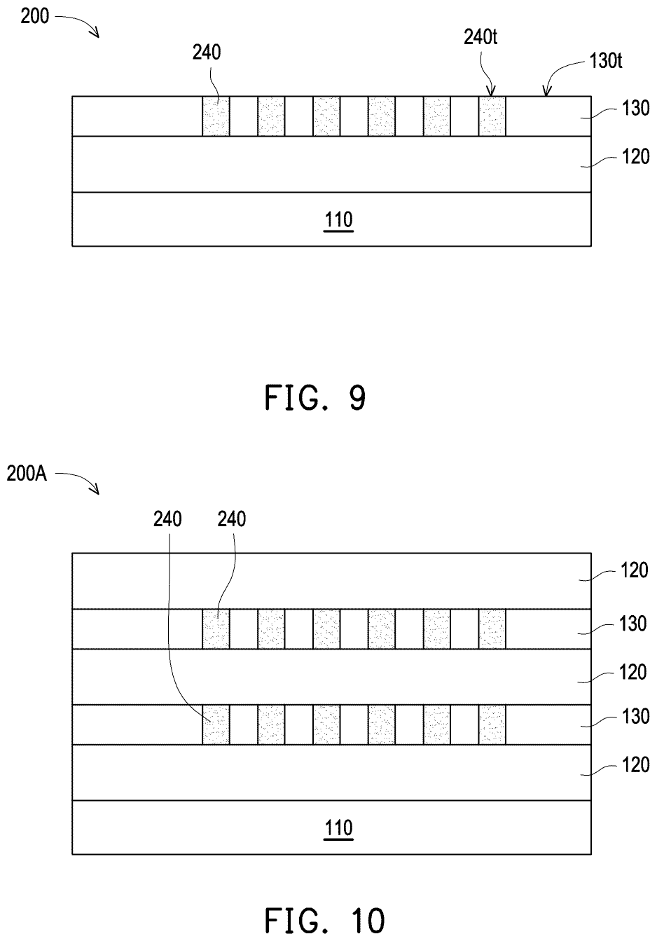

Referring to FIG. 8 to FIG. 9, an optical structure 240 is formed in the openings 30, wherein the optical structure 240 may be a functional structure. In the embodiment, the optical structure 240 is manufactured as follow. In FIG. 8, the optical structure 240 is formed on the photo-sensitive layer 130 and in the openings 30 by suitable deposition method. Next, in FIG. 9, a planarization process is performed, such that a top surface 130t of the photo-sensitive layer 130 is coplanar with a top surface 240t of the optical structure 240. Here, the planarization process may include CMP, grinding, chemical etching, or a combination thereof. The manufacturing of a package substrate 200 is roughly completed via the above steps.

In the embodiment, a refractive index of the dielectric layer 120 is smaller than a refractive index of the optical structure 240, such that the dielectric layer 120, the photo-sensitive layer 130, and the optical structure 240 are configured to an optical fiber array unit to let light pass through thereof. Here, materials of the optical structure 240 may be any suitable optical materials as long as the refractive index thereof is greater than the dielectric layer 120 and transparent that can transmit light in visible and/or infrared range.

It should be noted that the package substrate 200 having two layers is an example for illustrating, numbers of the package substrate 200 may be not limited, that is to say, in another embodiment, as shown in FIG. 10, for higher integrating, another two dielectric layer 120, another photo-sensitive layer 130, another optical structure 240 may be formed by similar method in FIG. 7 to FIG. 9 on the support structure 110 to constitute a package substrate 200A.

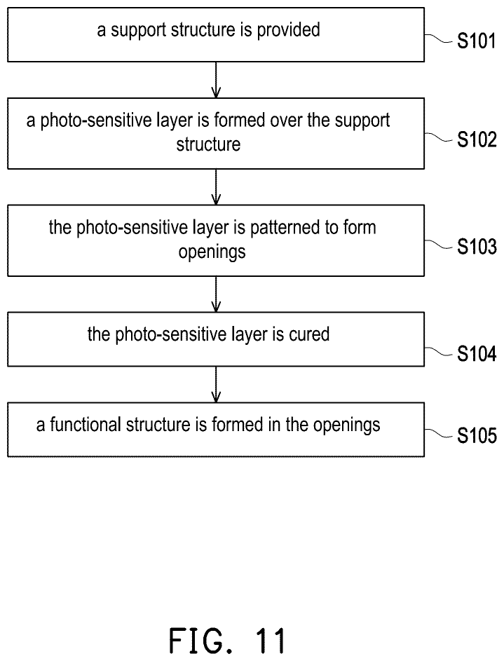

FIG. 11 is a flow diagram of some embodiments of a manufacturing method of a package substrate. The method includes a number of operations (blocks S101, S102, S103, S104, and S105). The description and illustration are not deemed as a limitation to the sequence of the operations.

At block S101, a support structure is provided. At block S102, a photo-sensitive layer is over the support structure. At block S103, the photo-sensitive layer is patterned to form openings. At block S104, the photo-sensitive layer is cured. FIG. 1 to FIG. 4 illustrate cross-sectional views of some embodiments corresponding to blocks S101, S102, S103, and S104, meanwhile FIG. 7 to FIG. 8 also illustrate cross-sectional views of some embodiments corresponding to blocks S101, S102, S103 and S104.

At block S105, a functional structure is formed in the openings. FIG. 4 illustrates a cross-sectional view of some embodiments corresponding to block S105, meanwhile FIG. 8 illustrates a cross-sectional view of some embodiments corresponding to block S105.

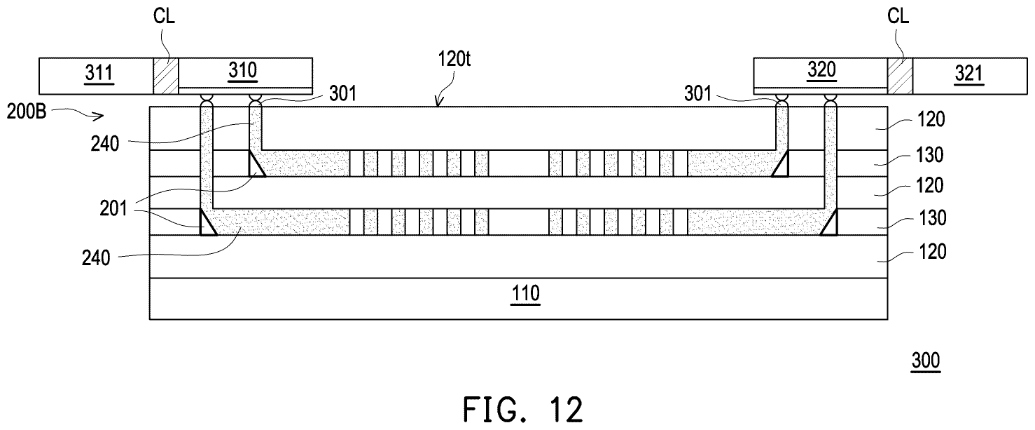

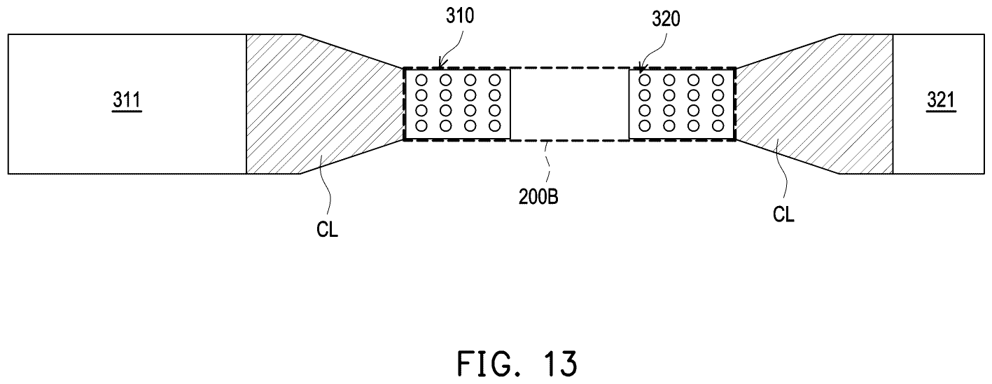

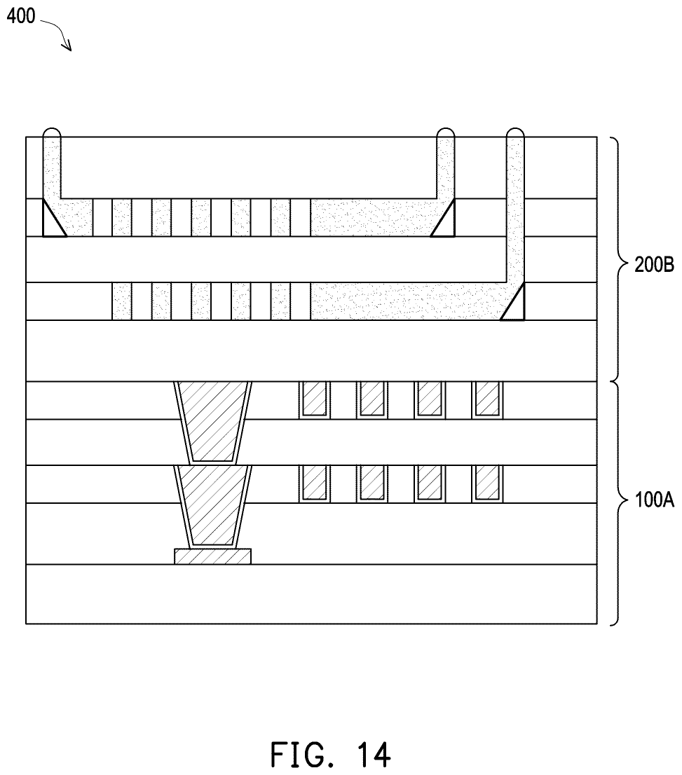

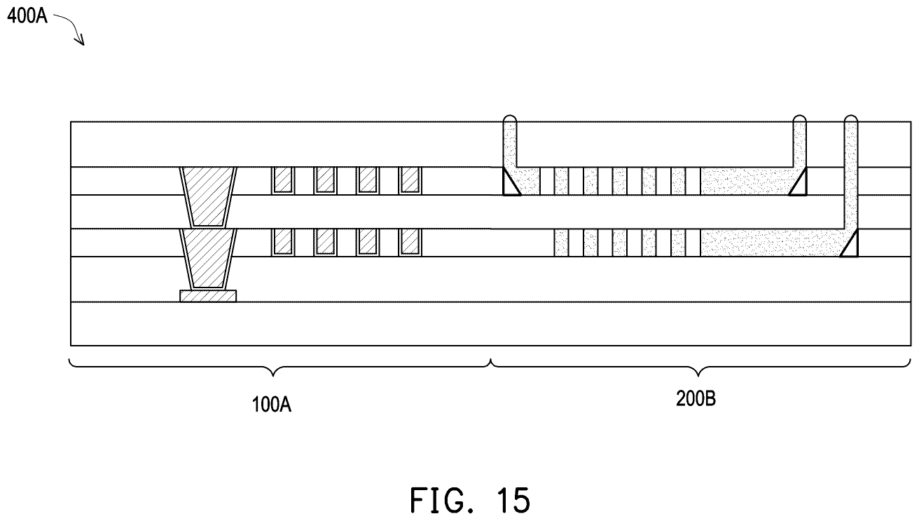

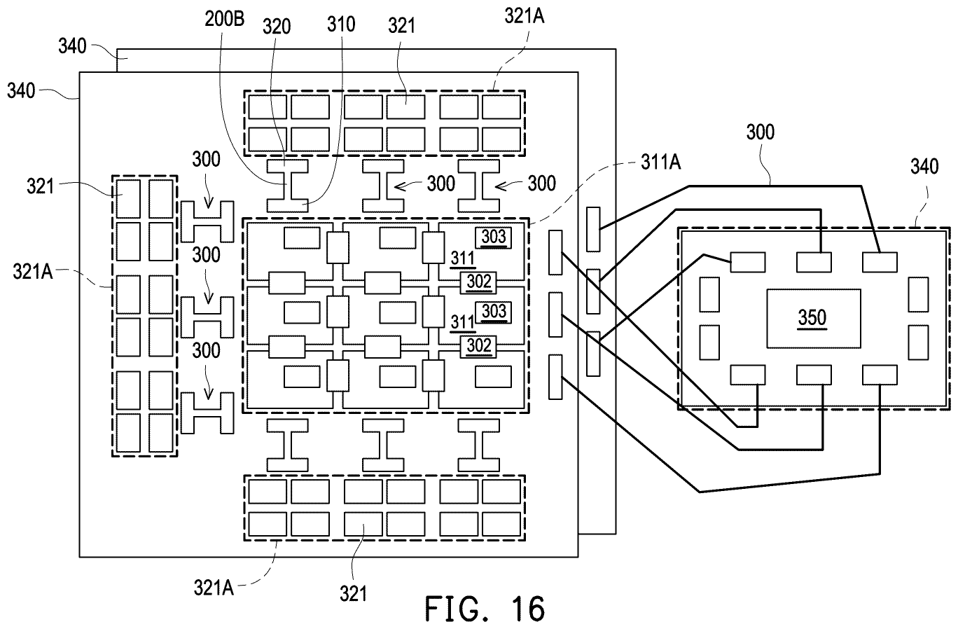

FIG. 12 is a partial schematic cross-sectional view illustrating an optical device according to some embodiments of the disclosure. FIG. 13 is a partial schematic top view corresponding to FIG. 12. FIG. 14 and FIG. 15 are partial schematic cross-sectional views illustrating a package substrate according to some embodiments of the disclosure. In the present disclosure, the package substrate 200B including the optical fiber array unit may be further used to constitute an optical device 300 for reducing energy consumption. Here, the package substrate 200B in FIG. 12 is similar to the package substrate 200A in FIG. 10 and the difference therebetween is the optical structure 240 is further extending to a top surface 120t of the dielectric layer 120 and a plurality of mirror 201 are optionally formed on the optical structure 240 to reflect the light in the package substrate 200B.

In the embodiment, the optical device 300 further includes a transceiver 310 and a transceiver 320 disposed on and electrically connected to the package substrate 200B respectively. To be specific, the package substrate 200B includes two set of the optical fiber array units (including two optical structure 240), wherein electrical signals and optical signals are transferred between the transceiver 310 and the transceiver 320 by two set of the optical fiber array units of the package substrate 200B, and the electrical signals and the optical signals are converted by the transceiver 310 and the transceiver 320, that is to say, there are two light path in the package substrate 200B provided by the two set of the optical fiber array units, therefore, the optical device 300 may be referred as a co-packaged optical (CPO) device.

In some embodiments, the transceiver 310 and/or the transceiver 320 is an array structure. For example, the transceiver 310 and/or the transceiver 320 includes a micro-LED array with lens providing electrical to optical (E/O) conversion, a photo diode array providing optical to electrical (O/E) conversion, or the like. Moreover, the transceiver 310 and the transceiver 320 may be connected to the package substrate 200B through a plurality of connectors 301.

In some embodiments, the transceiver 310 is electrically connected to a processor chip 311, and the transceiver 320 is electrically connected to a memory chip 321. Further, a plurality of connection lines CL may be formed, wherein one of connection lines CL is located between the transceiver 310 and the processor chip 311 and another one of connection lines CL is located between the transceiver 320 and the memory chip 321 for electrical connection.

The package substrate may have various alternative implementation in different design requirements. For example, In FIG. 14, the package substrate 400 is constituted by stacking the package substrate 100A and the package substrate 200B in a vertical direction. On the other hand, in FIG. 15, the package substrate 400A is constituted by arranging the package substrate 100A and the package substrate 200B side by side.

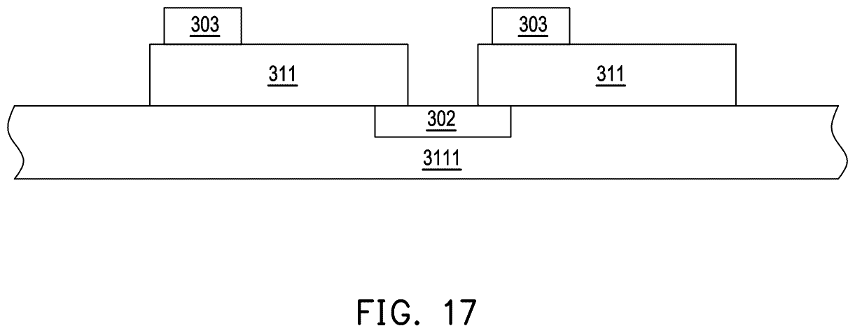

FIG. 16 is a partial schematic top view illustrating optical devices according to some embodiments of the disclosure. FIG. 17 is a partial schematic cross-sectional view illustrating optical devices according to FIG. 16. The optical device 300 may have various alternative implementation in different design requirements. In FIG. 16 and FIG. 17, multiple processor chips 311 (such as XPUs) may constitute to a sea of processor chip unit 311A, multiple memory chips 321 (such as HBMs) may constitute to a sea of memory chip unit 321A, and the sea of processor chip unit 311A may be electrically connected to sea of memory chip unit 321A by the optical device 300, wherein the sea of processor chip unit 311A and the sea of memory chip unit 321A are disposed on a circuit board 340. Here, the sea of processor chip unit 311A includes connection component 302 embedded in the substrate 3111 (localized interconnection such as silicon bridge as shown in FIG. 17) and L3 cache 303 bonded to the processor 311 for high bandwidth communication, but the disclosure is not limited thereto. In addition, a net-work switching chip 350 disposed beside the circuit board 340 is provided. The net-work switching chip 350 may be electrically connected to the circuit board 340 by the optical device 300. In some embodiments, one of the transceiver 310 and the transceiver 320 is optionally further electrically connected to a HPC module.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a package substrate, comprising:
providing a support structure;
forming a first photo-sensitive layer over the support structure;
patterning the first photo-sensitive layer to form first openings;
curing the first photo-sensitive layer; and
forming a functional structure in the first openings.

2. The manufacturing method of a package substrate according to claim 1, wherein the first photo-sensitive layer comprises photo-sensitive polyimide.

3. The manufacturing method of a package substrate according to claim 1, further comprising:
performing a photolithography process and an etching process to pattern the first photo-sensitive layer.

4. The manufacturing method of a package substrate according to claim 3, wherein the photolithography process comprises using photomasks or using a laser direct imaging tool.

5. The manufacturing method of a package substrate according to claim 1, further comprising:
performing a planarization process after forming the functional structure, such that a top surface of the first photo-sensitive layer is coplanar with a top surface of the functional structure.

6. The manufacturing method of a package substrate according to claim 1, wherein the support structure has a conductive trace, and the support structure is not removed after forming the functional structure.

7. The manufacturing method of a package substrate according to claim 1, wherein the support structure is free from a conductive trace, and the support structure is removed after forming the functional structure.

8. The manufacturing method of a package substrate according to claim 1, wherein the functional structure is a circuit structure.

9. The manufacturing method of a package substrate according to claim 8, wherein a manufacturing method of the circuit structure comprising:
forming a seed layer over the support structure by sputtering with Ti/Cu; and
forming a conductive layer on the seed layer by plating with Cu.

10. The manufacturing method of a package substrate according to claim 8, wherein the first openings have different depths.

11. The manufacturing method of a package substrate according to claim 1, wherein the functional structure is an optical structure.

12. The manufacturing method of a package substrate according to claim 11, further comprising:
forming a second photo-sensitive layer between the support structure and the first photo-sensitive layer; and
curing the second photo-sensitive layer to form a second photo-sensitive layer, wherein a refractive index of the second photo-sensitive layer is smaller than a refractive index of the optical structure, such that the first photo-sensitive layer, the second photo-sensitive layer, and the optical structure are configured to an optical fiber array unit.

13. An optical device, comprising:
a package substrate comprising a first optical fiber array unit;
a first transceiver disposed on and electrically connected to the package substrate; and
a second transceiver disposed on and electrically connected to the package substrate, wherein:
a first electrical signal and a first optical signal are transferred between the first transceiver and the second transceiver by the first optical fiber array unit; and
the first electrical signal and the first optical signal are converted by the first transceiver and the second transceiver.

14. The optical device according to claim 13, wherein the first optical fiber array unit comprises a first photo-sensitive layer, a second photo-sensitive layer disposed on the first photo-sensitive layer, and a first optical structure embedded in the second photo-sensitive layer.

15. The optical device according to claim 13, wherein:
the package substrate further comprising: a second optical fiber array unit;
a second electrical signal and a second optical signal are transferred between the first transceiver and the second transceiver by the second optical fiber array unit; and
the second electrical signal and the second optical signal are converted by the first transceiver and the second transceiver.

16. The optical device according to claim 15, wherein the second optical fiber array unit comprises a third photo-sensitive layer disposed on the first optical fiber array unit, a fourth photo-sensitive layer disposed on the third photo-sensitive layer, and a second optical structure embedded in the fourth photo-sensitive layer.

17. The optical device according to claim 13, wherein the package substrate further comprising: a circuit unit comprising a fifth photo-sensitive layer underlying or located beside the first optical fiber array unit and a circuit structure embedded in the fifth photo-sensitive layer.

18. The optical device according to claim 13, wherein one of the first transceiver and the second transceiver is electrically connected to a processor chip, and another one of the first transceiver and the second transceiver is electrically connected to a memory chip.

19. The optical device according to claim 13, wherein one of the first transceiver and the second transceiver is further electrically connected to a HPC module.

20. The optical device according to claim 13, wherein the first transceiver and/or the second transceiver is an array structure.
